(19) United States
(12) Patent Application Publication
(10) Pub. No.: US 2026/0068168 A1
(43) Pub. Date: Mar. 5, 2026

(54) MEMORY DEVICE HAVING SELF-SELECTING PROPERTY AND ELECTRONIC APPARATUS INCLUDING THE SAME

(71) Applicant: Samsung Electronics Co., Ltd., Suwon-si (KR)

(72) Inventors: Jongbong PARK, Suwon-si (KR); Youngjae KANG, Suwon-si (KR); Bonwon KOO, Suwon-si (KR); Kiyeon YANG, Suwon-si (KR); Minwoo CHOI, Suwon-si (KR); Yongnam HAM, Suwon-si (KR)

(73) Assignee: Samsung Electronics Co., Ltd., Suwon-si (KR)

(21) Appl. No.: 19/183,177

(22) Filed: Apr. 18, 2025

(30) Foreign Application Priority Data
Sep. 4, 2024 (KR) 10-2024-0120314

(51) Int. Cl. H10B 43/35; G11C 5/06; G11C 16/04; H10B 41/10; H10B 41/20; H10B 41/35; H10B 43/10; H10B 43/20

(52) U.S. Cl. CPC H10B 43/35; G11C 5/063; G11C 16/0483; H10B 41/10; H10B 41/20; H10B 41/35; H10B 43/10; H10B 43/20

(57) ABSTRACT

A memory device having self-selecting characteristics and an electronic apparatus including the same are disclosed. The memory device having self-selection characteristics includes a plurality of memory cells, each of the memory cells arranged between the first wiring and the second wiring at an intersection of first and second wirings that intersect each other, and including a memory material layer having a characteristic in which a threshold voltage is shifted according to an applied voltage. The memory material layer has a composition represented by A(x)D(y)M(z), wherein A includes germanium (Ge), D includes arsenic (As), and M includes tellurium (Te), and x may satisfy 0<x<0.45, z may satisfy 0.45<z<1, and y=1−(x+z).

### CROSS-REFERENCE TO RELATED APPLICATION

This application is based on and claims priority under 35 U.S.C. § 119 to Korean Patent Application No. 10-2024-0120314, filed on Sep. 4, 2024, in the Korean Intellectual Property Office, the disclosure of which is incorporated by reference herein in its entirety.

### BACKGROUND

Some example embodiments relate to a memory device and/or an electronic apparatus including the same, and more particularly, to a memory device having self-selecting properties and/or an electronic apparatus including the same.

Cross-point memory is or includes a type of memory composed of memory elements and switching devices at an intersection of word lines and bit lines, which may improve reliability, increase write and read speeds, and/or be advantageous for 3D stacking and high integration.

An ovonic threshold switch (OTS) has been used as a switching element to suppress a leak current of a cross-point memory. Recently, because it has been confirmed that the OTS also has a memory function, memories composed of memory cells using only OTS, e.g., without a corresponding access transistor, have been introduced.

Such memories are expressed as self-selecting memories (SSM) because the OTS acts as both a switching element and a memory element, as selector-only memories (SOM) because OTS was previously used as a selector switching element (selector), or as threshold switching memories (TSM) because the memory function of OTS is based on threshold voltage shift.

In an SSM, a memory cell has a simple structure including, e.g., consisting of only the OTS without separate switching elements, and the cell volume is also less than that of memories before the SSM, and thus, the SSM is attracting attention as a high-speed, high-density memory. However, in order to increase expandability, the operating power is to be lowered.

### SUMMARY

Provided is a memory material capable of lowering driving power and having self-selecting characteristics.

Alternatively or additionally, provided is a memory device including such a memory material.

Provided is an electronic apparatus including the memory device.

Additional aspects will be set forth in part in the description which follows and, in part, will be apparent from the description, or may be learned by practice of the presented embodiments of the disclosure.

A memory material comprises a composition represented by A(x)D(y)M(z), wherein A includes germanium (Ge), D includes arsenic (As), and M includes tellurium (Te), and x satisfies 0<x<0.45, z satisfies 0.45<z<1, and y=1−(x+z).

In some example embodiments, the memory material may further include a dopant. In one example, the dopant may include at least one of indium (In), selenium (Se), sulfur (S), antimony (Sb), nitrogen (N), and aluminum (Al).

According to some example embodiments, a memory material includes a plurality of memory cells, wherein each memory cell includes a memory material layer between a first wiring and a second wiring at an intersection of the first wiring and the second wiring intersecting each other, and the memory material having a characteristic in which a threshold voltage shifts depending on an applied voltage. The memory material layer may include a composition represented by A(x)D(y)M(z), wherein A includes germanium (Ge), D includes arsenic (As), M includes tellurium (Te), and x satisfies 0<x<0.45, z satisfies 0.45<z<1, and y=1−(x+z).

In some example embodiments, the first and second wirings and the memory material layer may be in direct contact with each other.

In some example embodiments, the memory material may further include a first electrode layer between a first side of the memory material layer and the first wiring, and a second electrode layer between a second side of the memory material layer and the second wiring, the second side different from the first side. The memory material may further include a first dielectric layer between the first side of the memory material layer and the first electrode layer. The memory material may further include a second dielectric layer between the second side of the memory material layer and the second electrode layer.

In some example embodiments, the memory material may further include a first dielectric layer between the memory material layer and the first wiring. The memory material may further include a second dielectric layer provided the memory material layer and the second wiring.

In some example embodiments, the memory device may have a three-dimensional cross point structure.

In some example embodiments, the memory device may include a vertical NAND (VNAND) structure. The plurality of memory cells may be arranged in a third direction perpendicular to a plane defined by the first and second directions.

In some example embodiments, the memory device may further include a plurality of word planes extending along a plane defined by the first and second directions and spaced apart in the third direction, a vertical bit line extending in the third direction through the plurality of word planes, and a memory cell string surrounding the vertical bit line and extending in the third direction. The memory cell string and the vertical bit line that are surrounded by each word plane and each word plane constitute or correspond to one memory cell.

In some example embodiments, the memory material layer may be configured to be in one of a first state having a first threshold voltage or a second state having a second threshold voltage higher than the first threshold voltage. The first threshold voltage may be a set threshold voltage, the second threshold voltage may be a reset threshold voltage, and the reset threshold voltage may be lower than 3V.

In some example embodiments, an electronic apparatus may include a memory device according to one or more of the above example embodiments. The electronic apparatus may further include a semiconductor circuit unit. The memory device may be a built-in memory for the semiconductor circuit unit and is included in one chip with the semiconductor circuit unit.

### BRIEF DESCRIPTION OF THE DRAWINGS

The above and other aspects, features, and advantages of certain example embodiments will be more apparent from the following description taken in conjunction with the accompanying drawings, in which:

FIG. 1 is a cross-sectional view of a first unit memory device (memory cell) of a self-selecting memory device according to some example embodiments;

FIG. 2 is a graph schematically illustrating a threshold voltage change of a memory material layer according to a voltage applied to the first unit memory device of FIG. 1;

FIG. 3 is a cross-sectional view showing a second unit memory device of a self-selecting memory device according to some example embodiments;

FIG. 4 is a cross-sectional view showing a third unit memory device of a self-selecting memory device according to some example embodiments;

FIG. 5 is a cross-sectional view showing a fourth unit memory device of a self-selecting memory device according to some example embodiments;

FIG. 6 is a graph showing a voltage-current relationship of the first unit memory device of FIG. 1 according to a component ratio when the memory material (material) used in the first unit memory device is GeAsTe;

FIG. 7 is a graph showing a read window margin of the first unit memory device of FIG. 1 when the memory material (material) used in the first unit memory device is first GeAsTe;

FIG. 8 is a graph showing a read window margin of the first unit memory device of FIG. 1 when the memory material (material) used in the first unit memory device is second GeAsTe;

FIG. 9 is a plan view showing a memory cell array of a self-selecting memory device according to some example embodiments;

FIG. 10 is a perspective view schematically showing a self-selecting memory device according to some example embodiments;

FIG. 11 is a plan view showing an operation of selecting a specific memory cell in the self-selecting memory device of FIG. 10;

FIG. 12 is a perspective view schematically showing a self-selecting memory device according to some example embodiments;

FIG. 13 is a vertical cross-sectional view schematically showing a structure of one memory cell in the self-selecting memory device of FIG. 12;

FIG. 14 is a horizontal cross-sectional view schematically showing a structure of one memory cell in the self-selecting memory device of FIG. 12;

FIG. 15 is a block diagram schematically showing a microchip according to some example embodiments.

FIG. 16 is a block diagram showing an electronic system according to some example embodiments;

FIG. 17 is a conceptual diagram schematically showing a device architecture that may be applied to an electronic apparatus according to some example embodiments;

FIG. 18 is a block diagram showing a memory system according to some example embodiments; and

FIG. 19 is a block diagram showing a neuromorphic apparatus according to some example embodiments and an external apparatus connected thereto.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a memory device having a self-selecting property and an electronic apparatus including the same will be described in detail with reference to the accompanying drawings. In the drawings, thicknesses of layers and regions may be exaggerated for clarification of the specification.

Some example embodiments are capable of various modifications and may be embodied in many different forms. In a layer structure described below, when an element or layer is referred to as being “on” or “above” another element or layer, the element or layer may be directly on another element or layer or intervening elements or layers. In the following drawings, like reference numerals refer to the like elements

The singular forms include the plural forms unless the context clearly indicates otherwise. When a part “comprises” or “includes” a constituent element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise the operations may not necessarily be performed in the order of sequence.

Also, in the specification, the term “units” or “ . . . modules” denote units or modules that process at least one function or operation, and may be realized by hardware, software, or a combination of hardware and software

The connections of lines and connection members between constituent elements depicted in the drawings are examples of functional connection and/or physical or circuitry connections, and thus, in practical devices, may be expressed as replaceable or additional functional connections, physical connections, or circuitry connections.

All examples or example terms are simply used to explain in detail the technical scope of inventive concepts, and thus, the scope of inventive concepts is not limited by the examples or the example terms as long as it is not defined by the claims.

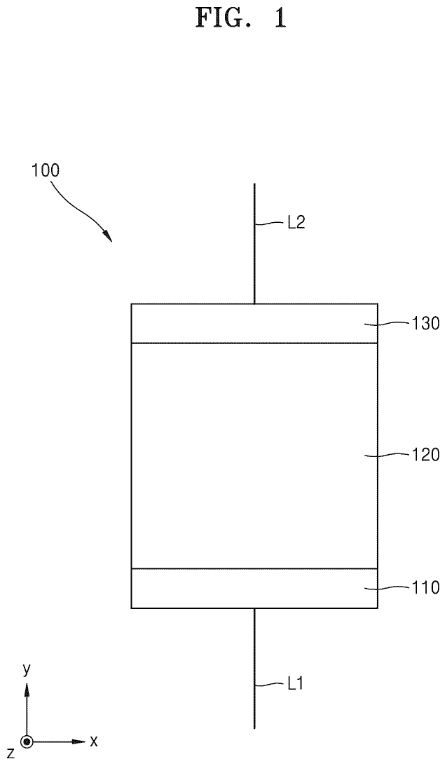

FIG. 1 is a cross-sectional view of a first unit memory device (memory cell) 100 of a self-selecting memory device according to some example embodiments.

Referring to FIG. 1, the first unit memory device 100 includes a first electrode layer 110, a second electrode layer 130 spaced apart from the first electrode layer 110, and a memory material layer 120 disposed between the first electrode layer 110 and the second electrode layer 130. The first electrode layer 110 and the second electrode layer 130 may be disposed to face each other. The first electrode layer 110 and the second electrode layer 130 may include one or more of a metal, a conductive metal nitride, a conductive metal oxide, or any combination thereof. For example, the first electrode layer 110 and the second electrode layer 130 may include at least one or any combination of titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tantalum silicon nitride (TaSiN), tantalum aluminum nitride (TaAlN), tungsten silicide (WSi), titanium tungsten (TiW), molybdenum nitride (MoN), niobium nitride (NbN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), titanium aluminum (TiAl), titanium oxynitride (TiON), titanium aluminum oxynitride (TiAlON), tungsten oxynitride (WON), tantalum oxynitride (TaON), silicon carbon (SiC), silicon carbon nitride (SiCN), carbon nitride (CN), tantalum carbon nitride (TaCN), tungsten (W), tungsten nitride (WN), and carbon (C). The first electrode layer 110 and the second electrode layer 130 may include the same, and/or different, materials or elements; example embodiments are not limited thereto.

The memory material layer 120 may be in contact with, e.g., in direct contact with, either or both of the first electrode layer 110 and the second electrode layer 130 between the first electrode 110 and the second electrode layer 130, but is not limited thereto. The memory material layer 120 may also be expressed as a memory layer. The first electrode layer 110, the memory material layer 120, and the second electrode layer 130 may be sequentially stacked in a first direction (e.g., in a y-axis direction). A first wiring L1 may be connected to the first electrode layer 110, and a second wiring L2 may be connected to the second electrode layer 130. One of the first and second wirings L1 and L2 may be a row line or a word line, and another may be a column line or a bit line. Therefore, the first unit memory device 100 may be placed between the bit line and the word line.

The memory material layer 120 may be or may include a material layer having threshold voltages of different magnitudes depending on the polarity and/or strength of an applied voltage. In some example embodiments, the memory material layer 120 may include an amorphous material layer but is not limited thereto.

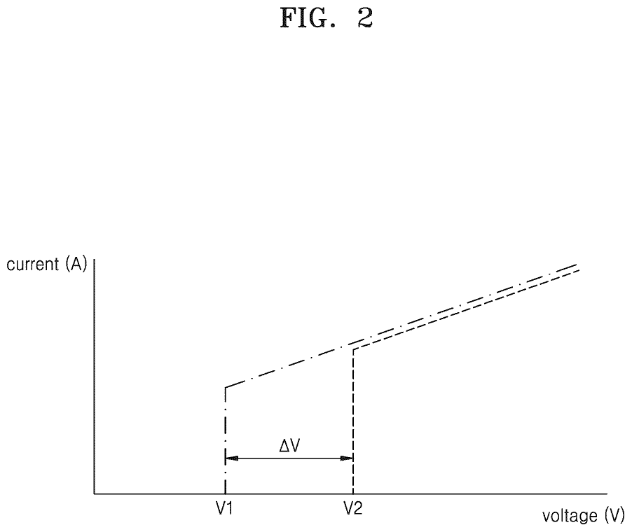

FIG. 2 is a graph schematically illustrating a threshold voltage change of the memory material layer 120 according to a voltage applied to the unit memory cell 100.

Referring to FIG. 1 and FIG. 2 together, after a positive (+) bias voltage is applied to or across the unit memory cell 100 in a first direction (e.g., the +direction of the y-axis) for the initial driving of the unit memory cell 100, the memory material layer 120 has a threshold voltage characteristic by which a significant current starts to flow above a first voltage V1. For example, after the positive bias voltage for the first drive is applied, the memory material layer 120 has a first state in which the memory material layer 120 is turned on at the first voltage V1 or higher. Therefore, the first voltage V1 may be referred to as a first threshold voltage.

When the memory material layer 120 is in the first state, if a negative bias voltage is applied to or across the first unit memory device (memory cell) 100 in a second direction (e.g., a negative (−) direction of the y-axis) that is the opposite direction to the first direction, the memory material layer 120 has a threshold voltage characteristic by which significant current flows at a second voltage V2 greater than the first voltage V1 and almost no current flows at a voltage lower than the second voltage V2. For example, after the negative bias voltage is applied, the memory material layer 120 has a second state in which the memory material layer 120 is turned on at the second voltage V2 or higher. Therefore, the second voltage V2 may be referred to as a second threshold voltage that is greater than the first threshold voltage. When a positive bias voltage greater than the second voltage V2 is applied to the memory material layer 120 having the second state, the state of the memory material layer 120 may change from the second state to the first state. An absolute value of the negative (−) bias voltage applied to the first unit memory device (memory cell) 100 may be equal to or substantially equal to the absolute value of the first voltage V1. A process of changing the state of the memory material layer 120 from the first state to the second state may be referred to as a reset process, and the opposite process may be referred to as a set process.

When the memory material layer 120 has a first threshold voltage, it may be considered that first data is stored in the memory material layer 120, and when the memory material layer 120 has a second threshold voltage, it may be considered that second data is stored in the memory material layer 120. One of the first and second data may be bit “0”, and the other may be bit “1”.

Because the threshold voltage of the memory material layer 120 varies depending on the polarity of and/or intensity of a voltage applied to the memory material layer 120, the memory material layer 120 may also be expressed as a variable threshold voltage material layer.

The behavior of shifting the threshold voltage of the memory material layer 120 depending on the polarity of the applied voltage may be explained through the change in a trap state inside the memory material layer 120, which is described in detail in Korean Patent Application No. 10-2023-0124090 (2023 Sep. 18), the contents of which are herein incorporated in their entirety.

In FIG. 2, a difference ΔV (e.g., a difference V2−V1) between the first voltage V1 and the second voltage V2 may have a value or range that may read data recorded in the memory material layer 120 without error and does not affect the recorded data. The difference ΔV may correspond to one or more of a data read margin, a read window, or a memory window, and a read voltage between the first voltage V1 and the second voltage V2 may be applied to the first unit memory device (memory cell) 100 as a data read operation. By applying the read voltage and comparing the current or resistance measured from the first unit memory device (memory cell) 100 with a reference current or reference resistance, data recorded in the memory material layer 120 may be read.

In this way, because the memory material layer 120 may have a threshold voltage, the memory material layer 120 may act as a selector for selecting a memory cell. In some example embodiments, the memory material layer 120 may have different threshold voltages depending on the applied voltage and provide a read window, and thus, may also be a memory that may store data. As a result, the memory material layer 120 may be expressed as a dual-function material layer and/or a multi-functional material layer, etc.

In some example embodiments, the memory material layer 120 may be a ternary amorphous material layer or may include such a material layer, but is not limited thereto. In some example embodiments, the ternary amorphous material layer may be doped with a doping material. For example, the ternary amorphous material layer may include a dopant. In some example embodiments, the dopant may include at least one of indium (In), selenium (Se), sulfur (S), antimony (Sb), nitrogen (N), and aluminum (Al).

In some example embodiments, the ternary amorphous material layer may include a chalcogenide including a chalcogen element. In some example embodiments, the ternary amorphous material layer may include a chalcogenide of A(x)D(y)M(z). In some example embodiments, in “A(x)D(y)M(z)”, A may be or may include Ge, but is not limited thereto, D may be or may include As, but is not limited thereto, and M may be or may include Te as a chalcogen, but is not limited thereto. In some example embodiments, in “A(x)D(y)M(z)”, ‘x’ may be greater than 0 and less than 0.45 (45 at %) (0<x<0.45). For example, ‘x’ may be less than or equal to 0.43 (43 at %), or less than or equal to 0.40 (40 at %), but is not limited to this range. In “A(x)D(y)M(z)”, ‘z’ may be greater than or equal to 0.45 (45 at %) and less than 1 (0.45<z<1). For example, ‘z’ may be 0.48 (48 at %) or more, 0.50 (50 at %) or more, 0.54 (54 at %) or more, or 0.55 (55 at %) or more, but is not limited to this range. In “A(x)D(y)M(z)”, ‘y’ may have a range of 1−(x+z).

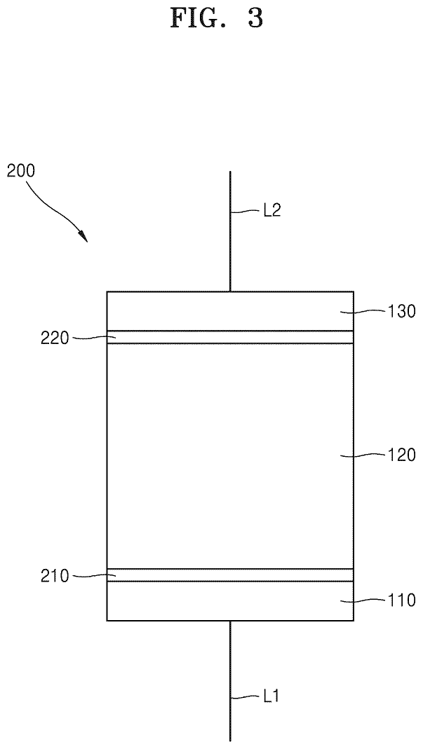

FIG. 3 shows a second unit memory device (memory cell) 200 of a self-selecting memory device according to some example embodiments. Only the parts that are different from the first unit memory device 100 of FIG. 1 are described.

Referring to FIG. 3, the second unit memory device 200 includes a first dielectric film 210 between the memory material layer 120 and the first electrode layer 110. The first dielectric film 210 may fill, e.g., may completely fill between the first electrode layer 110 and the memory material layer 120. The first dielectric film 210 may be in direct contact with the first electrode layer 110 and the memory material layer 120. The entire surface of the first electrode layer 110 facing the first dielectric film 210 may be covered with the first dielectric film 210. The entire surface of the memory material layer 120 facing the first dielectric film 210 may be covered with the first dielectric film 210. A thickness of the first dielectric film 210 may be different from that of the first electrode layer 110 and the memory material layer 120. For example, the first dielectric film 210 may have a thickness less than the first electrode layer 110 and less than the memory material layer 120. The first dielectric film 210 may have a material and/or thickness that may expand the read window (ΔV in FIG. 2) of the memory material layer 120. In some example embodiments, the first dielectric film 210 may include silicon nitride SiN and may have a thickness of less than 5 nm. In some example embodiments, the thickness of the first dielectric film 210 may be greater than 0 and less than or equal to 4 nm, less than or equal to 3 nm, or less than or equal to 2 nm. In another example, the first dielectric film 210 may have a thickness of about 0.5 nm to 2 nm, 1 nm to 3 nm, or 2 nm to 4 nm, but is not limited thereto.

The first dielectric film 210 may have a thickness that is uniform or substantially uniform throughout.

In some example embodiments, a second dielectric film 220 may alternatively or additionally be provided between the memory material layer 120 and the second electrode layer 130. The arrangement relationship (shape) between the second dielectric film 220, the second electrode layer 130, and the memory material layer 120 may be the same as the arrangement relationship (shape) between the first dielectric film 210, the first electrode layer 110, and the memory material layer 120. The material and/or thickness of the second dielectric film 220 may be the same as the material and/or thickness of the first dielectric film 210, but may be different from each other. In some example embodiments, both the first dielectric film 210 and the second dielectric film 220 may be provided, or only one of them may be provided.

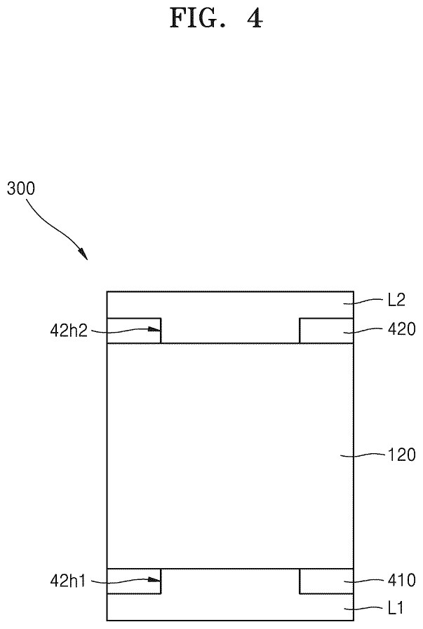

FIG. 4 shows a third unit memory device (memory cell) 300 of a self-selection memory according to some example embodiments. Only parts different from the first unit memory device 100 of FIG. 1 are described.

Referring to FIG. 4, the third unit memory device 300 may correspond to a case in which the first and second electrode layers 110 and 130 are omitted from the first unit memory device 100 of FIG. 1, and the first wiring L1 and the second wiring L2 are in direct contact with the memory material layer 120. A first insulating layer 410 may be provided on a bottom surface of the memory material layer 120. The first insulating layer 410 may include a first through hole 42h1. The bottom surface of the memory material layer 120 is exposed through the first through hole 42h1. The first wiring L1 may be formed on a bottom surface of the first insulating layer 410 to fill the first through hole 42h1. The first through hole 42h1 may be completely filled with the first wiring L1, and the first wiring L1 may be in contact with the entire bottom surface of the memory material layer 120 exposed through the first through hole 42h1. A second insulating layer 420 may be provided on an upper surface of the memory material layer 120. A second through hole 42h2 may be formed in the second insulating layer 420. The upper surface of the memory material layer 120 may be exposed through the second through hole 42h2. The second through hole 42h2 may be completely filled with the second wiring L2. The second wiring L2 may be in contact with the entire upper surface of the memory material layer 120 exposed through the second through hole 42h2.

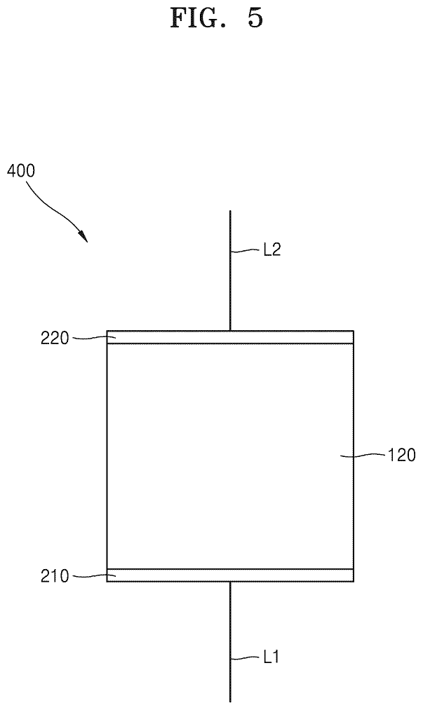

FIG. 5 shows a fourth unit memory element (memory cell) 400 of a self-selection memory according to some example embodiments.

The fourth unit memory device 400 may correspond to a case in which the first dielectric film 210 and the second dielectric film 220 of the second unit memory device 200 of FIG. 3 are applied to the third unit memory device 300 of FIG. 4.

Specifically, referring to FIG. 5, the first dielectric film 210 is provided between the memory material layer 120 and the first wiring L1, and the second dielectric film 220 is provided between the memory material layer 120 and the second wiring L2. The first dielectric film 210 covers an entire bottom surface of the memory material layer 120 and may be in direct contact with the entire bottom surface of the memory material layer 120. The first dielectric film 210 may be in direct contact with the first wiring L1. The second dielectric film 220 covers an entire upper surface of the memory material layer 120 and may be in direct contact with the entire upper surface of the memory material layer 120. The second dielectric film 220 may be in direct contact with the second wiring L2.

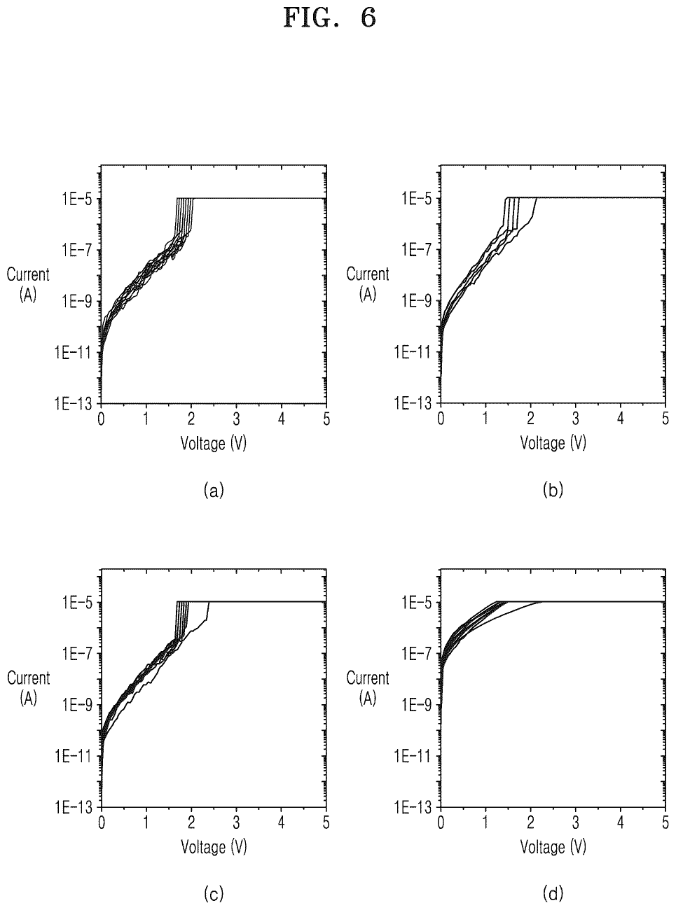

When the memory material layer 120 expressed as an ADM of a self-memory device according to some example embodiments is a GeAsTe layer, an example embodiment performed to confirm whether a threshold voltage appears in the memory material layer 120 and whether the threshold voltage changes (shifts) depending on an applied voltage, and a comparative example performed for comparing with the example embodiment will be described. The results of the above embodiments and comparative examples are shown in FIGS. 6 to 8 and summarized in Table 1 below.

TABLE 1

| | | | | | Set | Reset | |
|---|---|---|---|---|---|---|---|
| | | | | Vth | Vth | Vth | ΔVth |
| # | Ge(at %) | As(at %) | Te(at %) | (V) | (V) | (V) | (V) |
| [Embodiment 1] | 21 | 25 | 54 | 1.85 | 1.71 | 2.54 | 0.83 |
| [Embodiment 2] | 36 | 9 | 55 | 1.6 | 1.47 | 2.41 | 0.94 |
| [Embodiment 3] | 31 | 19 | 50 | 1.75 | 1.39 | 2.37 | 0.98 |
| [Comparative | 46 | 9 | 45 | Leakage fail | | | |
| example] | | | | | | | |

Example embodiments were divided into first to third embodiments according to the content or composition of germanium (Ge) and tellurium (Te).

The first example embodiment is performed to confirm whether a threshold voltage exists and whether a threshold voltage shift occurs depending on an applied voltage with respect to a GeAsTe memory material having a Ge content of 21 at % and a Te content of 54 at %.

The second example embodiment is performed to confirm whether a threshold voltage exists and whether a threshold voltage shift occurs depending on an applied voltage with respect to a GeAsTe memory material having a Ge content of 36 at % and a Te content of 55 at %.

The third example embodiment is performed to confirm whether a threshold voltage exists and whether a threshold voltage shift occurs depending on an applied voltage with respect to a GeAsTe memory material having a Ge content of 31 at % and a Te content of 50 at %.

The comparative example is performed to confirm whether a threshold voltage exists and whether a threshold voltage shift occurs depending on an applied voltage when the Ge content and Te content of the memory material layer 120 are different from the first to third embodiments, that is, when the Ge content and Te content of the memory material layer 120 are out of the ranges exemplified in the description referring to FIGS. 1 and 2.

The comparative example was performed with respect to a GeAsTe memory material having a Ge content of 46 at % and a Te content of 45 at %.

In the first to third example embodiments and comparative example, a current is measured while applying a DC voltage to the GeAsTe memory material to confirm whether a threshold voltage exists in the GeAsTe memory material.

In addition, in the first and third example embodiments, the set process and the reset process were performed on the GeAsTe memory material to confirm whether the threshold voltage of the GeAsTe memory material shifts according to the polarity of the applied voltage, and it was confirmed whether the threshold voltage appears in the GeAsTe memory material that went through each process. A positive pulse voltage is used in the set process, and a negative pulse voltage is used in the reset process. The threshold voltage that appears in the GeAsTe memory material that has gone through the above set process is conveniently called a set threshold voltage ‘set Vth’, and the threshold voltage that appears in the GeAsTe memory material that has gone through the above reset process is called a reset threshold voltage ‘reset Vth’. The reset threshold voltage may be greater than the set threshold voltage. The set threshold voltage may correspond to the threshold voltage when the memory material layer 120 of FIG. 1 is in the first state. The reset threshold voltage may correspond to the threshold voltage when the memory material layer 120 of FIG. 1 is in the second state.

FIG. 6 shows results of an example embodiment and a comparative example performed to confirm whether a threshold voltage exists in the GeAsTe memory material. In FIG. 6, (a) shows a result of the first example embodiment, (b) shows a result of the second example embodiment, (c) shows a result of the third example embodiment, and (d) shows a result of the comparative example.

Referring to (a) to (d) of FIG. 6, in the cases of (a) to (c), the threshold voltage appears at 2 V or below. On the other hand, in the case of (d), the threshold voltage does not appear, and a leakage fail state that may not block leakage current appears.

The results of FIG. 6 suggest that GeAsTe memory materials having a Ge content of less than 46% and a Te content of greater than 45 at % are suitable for use in SSMs or SOMs.

Alternatively or additionally, the results of FIG. 6 and Table 1 suggest that by appropriately adjusting the Ge and Te contents of the GeAsTe memory material, the threshold voltage may be lowered to within 2 V, that is, lowered to less than 2 V, which suggests that the operating power of SSMs or SOMs using GeAsTe memory materials may be lowered. Therefore, the SSM including the GeAsTe memory material according to the embodiment may be extended to other fields that require high-density memory with low power operation as well as embedded memory.

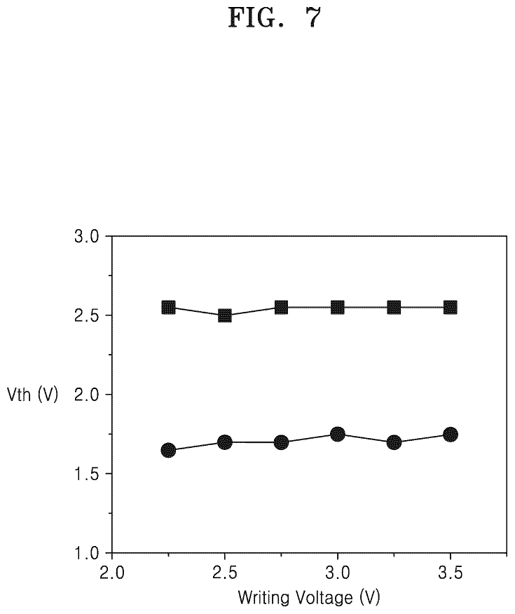

FIG. 7 shows results of measuring a set threshold voltage and a reset threshold voltage after performing the set process and the reset process on the GeAsTe memory material in the first example embodiment. In FIG. 7, the graph connected by circular shapes represents the set threshold voltage at each writing voltage, and the graph connected by rectangular shapes represents the reset threshold voltage at each writing voltage.

Referring to FIG. 7, the set threshold voltages are less than 2 V, the reset threshold voltages are greater than 2 V and less than 3 V, and there is an average voltage difference (ΔVth) of 0.83 V between the set threshold voltages and the reset threshold voltages, and a minimum voltage difference is also 0.5 V or more.

The set threshold voltage and the reset threshold voltage of the first embodiment of Table 1 correspond to the average of the set threshold voltages and the average of the reset threshold voltages shown in FIG. 7, respectively.

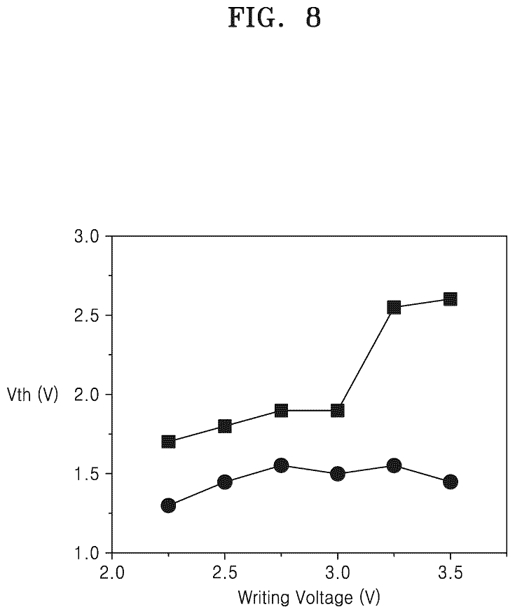

FIG. 8 shows results of measuring the set threshold voltage and the reset threshold voltage after performing the set process and the reset process on the GeAsTe memory material in the third example embodiment. In FIG. 8, the graph connected by circular shapes represents the set threshold voltage at each writing voltage, and the graph connected by rectangular shapes represents the reset threshold voltage at each writing voltage.

Referring to FIG. 8, the deviation of a voltage difference between the set threshold voltage and the reset threshold voltage at each writing voltage is relatively large compared to the results of the first embodiment of FIG. 7. However, a valid voltage difference between the set threshold voltage and the reset threshold voltage clearly exists at each writing voltage, which denotes that the threshold voltage of the GeAsTe memory material shifts depending on the polarity of the voltage applied to the GeAsTe memory material similar to the results shown in FIG. 7. In addition, the set threshold voltages are less than 2 V, the reset threshold voltages are greater than the set threshold voltage but less than 3 V, and there is an average voltage difference ΔVth of 0.98 V between the set threshold voltages and the reset threshold voltages.

The set threshold voltage and the reset threshold voltage of the third embodiment of Table 1 correspond to the average of the set threshold voltages and the average of the reset threshold voltages shown in FIG. 8, respectively.

The results of FIGS. 7 and 8 suggest that the threshold voltage shifts depending on the polarity of the voltage applied to the GeAsTe memory material although there is a difference depending on the contents of Ge and Te in the GeAsTe memory material. In addition, the results of FIGS. 7 and 8 show that not only the set threshold voltage but also the reset threshold voltage is less than 3 V, and the difference in threshold voltage before and after the shift (reset threshold voltage-set threshold voltage) is greater than 0.5 V, which suggests that sufficient memory window may be provided. Therefore, if a self-selecting memory according to some example embodiments including a GeAsTe memory material is used, it may be possible to reduce a driving power without a data read error while maintaining high integration.

Referring to Table 1, in the case of the second embodiment, as in the cases of the first and third embodiments, the threshold voltage and the set threshold voltage of the GeAsTe memory material are 2 V or less, the reset threshold voltage is 3 V or less, and the voltage difference between the set threshold voltage and the reset threshold voltage is 0.94 V on average, which is greater than 0.5 V.

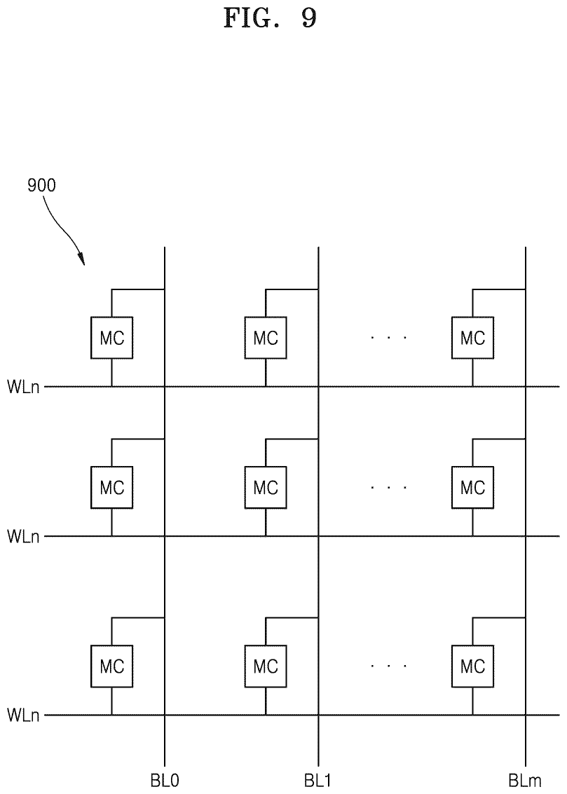

FIG. 9 shows a self-selecting memory device 900 according to some example embodiments.

Referring to FIG. 9, the self-selecting memory device 900 may include a plurality of self-selecting memory cells MC arranged one at each cross point, e.g., each region where a plurality of word lines WL0, WL1, . . . , WLn (n is a natural number greater than or equal to 2) and a plurality of bit lines BL0, BL1, . . . , BLm (m is a natural number greater than or equal to 2 that may or may not be equal to n) cross each other. In some example embodiments, each of the self-selecting memory cells MC may include any one of or other of the first to fourth unit memory devices 100, 200, 300, and 400 illustrated in FIGS. 1, 3, 4, and 5. In some example embodiments, the first to fourth unit memory devices 100, 200, 300, and 400 may be arranged as a two-feature-square (2F2) cross-point memory device; example embodiments are not limited thereto.

Each self-selecting memory cell MC may be connected between each word line among the plurality of word lines WL0 to WLn and each bit line among the plurality of bit lines BL0 to BLm. In this case, a voltage applied to each self-selecting memory cell MC may correspond to a voltage difference between each bit line and each word line. The plurality of word lines WL0 to WLn and the plurality of bit lines BL0 to BLm may be connected to write/read circuits (not shown) arranged around a cell array. The self-memory may also include write/read circuits.

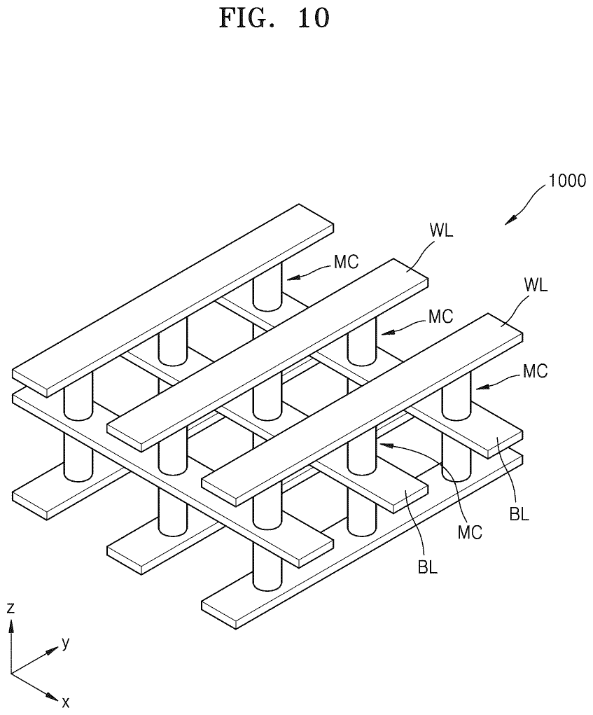

FIG. 10 is a perspective view schematically showing a self-selecting memory device 1000 according to some example embodiments.

Referring to FIG. 10, the self-selecting memory device 1000 may have a three-dimensional (3D) cross point structure. For example, the self-selecting memory device 1000 may include a plurality of bit lines BL extending in a first direction (e.g., the x-axis direction), a plurality of word lines WL extending in a second direction (e.g., the y-axis direction) intersecting the first direction, and a plurality of memory cells MC provided at points where the plurality of bit lines BL and the plurality of word lines WL cross each other.

Each of the plurality of memory cells MC may have a bar shape and may correspond to any one of, e.g., the same or different ones of, the first to fourth unit memory devices 100, 200, 300, and 400 illustrated in FIGS. 1, 3, 4, and 5.

In this structure, the memory cell MC may be driven by a potential difference between the word line WL and the bit line BL connected to both ends of each memory cell MC. For example, in the case when the memory material layer 120 is in a first state having a relatively low first threshold voltage, if a potential difference between the word line WL and the bit line BL is, for example, −2 V or less, the memory material layer 120 may change to a second state having a relatively high second threshold voltage. In addition, in the case when the memory material layer 120 is in a second state having a second threshold voltage, if the potential difference between the word line WL and the bit line BL is equal to or greater than the second threshold voltage, for example, +3 V or more, the memory material layer 103 may change to a first state having a relatively low first threshold voltage. When reading data recorded in the memory material layer 120, the potential difference between the word line WL and the bit line BL may be between the first threshold voltage and the second threshold voltage, for example, about +2 V.

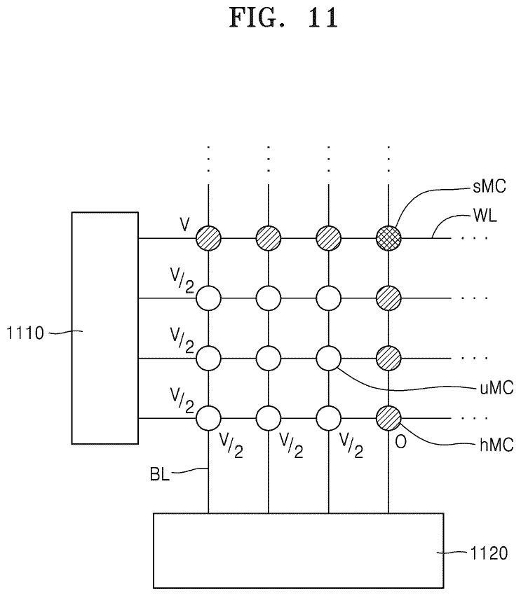

FIG. 11 is a plan view showing an operation of selecting a specific memory cell in the self-selecting memory device 1000 illustrated in FIG. 10.

Referring to FIG. 11, the self-selecting memory device 1000 may further include a row decoder 1110 that selectively supplies voltage to a plurality of word lines WL and a column decoder 1120 that selectively supplies voltage to a plurality of bit lines BL. In order to apply a voltage of V to one selected memory cell sMC among the plurality of memory cells MC, the row decoder 110 may provide the voltage of V to the word line WL connected to the selected memory cell sMC and provide a voltage of V/2 to the remaining word lines WL. At this time, the column decoder 1120 may provide a voltage of 0 V to the bit line BL connected to the selected memory cell sMC and provide a voltage of V/2 to the remaining bit lines BL.

Then, a potential difference between the word line WL and the bit line BL of the selected memory cell sMC becomes V. On the other hand, the potential difference between the word line WL provided with the voltage of V/2 and the bit line BL provided with the voltage of V/2 becomes 0 V. Therefore, no voltage is applied to unselected memory cell uMC arranged between the word line WL and the bit line BL that are not connected to the selected memory cell sMC.

Meanwhile, a voltage of V/2 may be applied to both ends of semi-selected memory cell hMC connected to the same word line WL as the selected memory cell sMC or connected to the same bit line BL as the selected memory cell sMC. Because each of the plurality of memory cells MC is a self-selecting memory device having a threshold voltage as described above, even if a voltage of V/2 is applied to a semi-selecting memory cell hMC adjacent to the selected memory cell sMC, the semi-selecting memory cell hMC does not turn on, and as a result, almost no sneak current occurs.

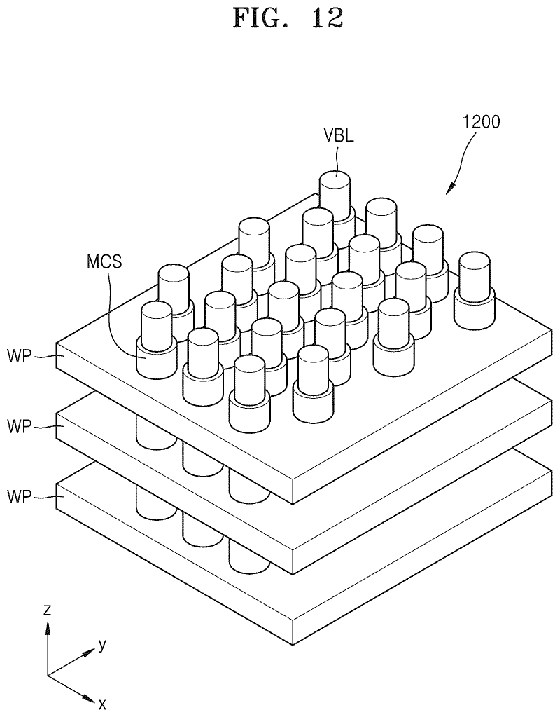

FIG. 12 schematically shows a self-selecting memory device 1200 according to some example embodiments.

Referring to FIG. 12, the self-selecting memory device 1200 may include a plurality of word planes WP extending along a plane including a first direction and a second direction and spaced apart from each other in a third direction (e.g., a z-axis direction) intersecting the first direction and the second direction, a plurality of vertical bit lines VBL extending in the third direction and arranged in the first direction and the second direction to form a two-dimensional array, and a plurality of memory cell strings MCS surrounding surfaces of the plurality of vertical bit lines VBL and extending in the third direction. The plurality of memory cell strings MCS may form a two-dimensional array by being arranged in the first direction and the second direction, similarly to the plurality of vertical bit lines VBL. Each of the plurality of memory cell strings MCS and each of the plurality of vertical bit lines VBL may be arranged to penetrate the plurality of word planes WP in the third direction. Because each of the plurality of memory cell strings MCS extends in the vertical direction, the self-selecting memory device 1200 may be called a vertical memory device (e.g., a vertical NAND (VNAND) memory device) and may have a further increased memory capacity. Each of the plurality of memory cell strings MCS may include the same material as the memory material layer 120 of the first unit memory device 100 illustrated in FIG. 1.

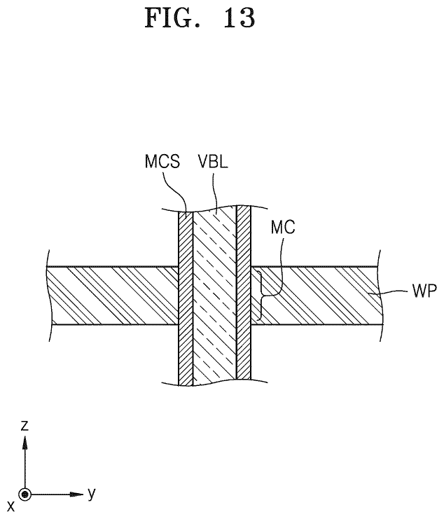

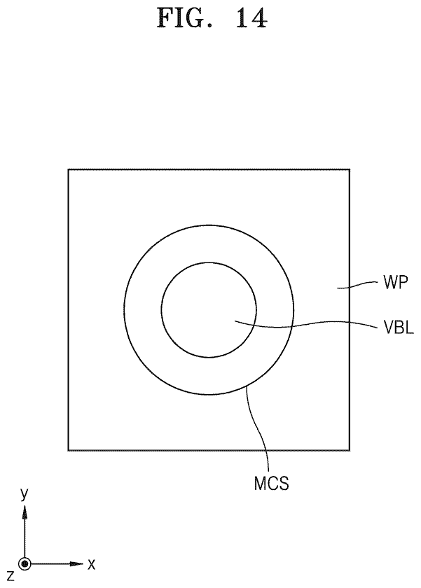

FIG. 13 is a vertical cross-sectional view schematically showing the structure of one memory cell in the self-selecting memory device 1200 illustrated in FIG. 12. FIG. 14 is a horizontal cross-sectional view schematically showing the structure of one memory cell in the self-selecting memory device 1200 illustrated in FIG. 12.

Referring to FIGS. 13 and 14, a vertical bit line VBL and a memory cell string MCS that are surrounded by the word plane WP and each word plane WP may constitute one memory cell. Here, the memory cell may correspond to one of the first to fourth unit memory devices 100, 200, 300, and 400 illustrated in FIGS. 1, 3, 4, and 5, or may be configured to correspond to one. In the self-selecting memory device 1200, the word plane WP and the vertical bit line VBL are in direct contact with the memory cell string MCS, which means that the word plane WP and the vertical bit line VBL themselves serve as electrode layers, and thus, the self-selecting memory device 1200 may directly correspond to the third unit memory cell illustrated in FIG. 4. The memory cell string MCS may correspond to the memory material layer 120 of the first unit memory device 100 illustrated in FIG. 1 and may have the same or similar memory characteristics as the memory material layer 120.

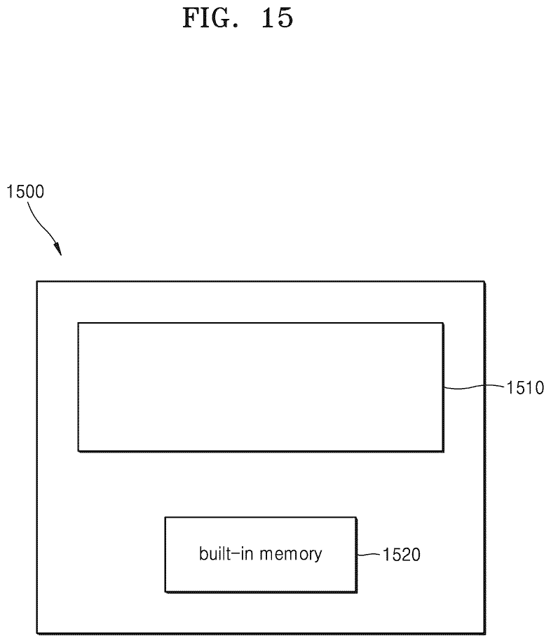

FIG. 15 schematically illustrates a microchip 1500 according to some example embodiments.

Referring to FIG. 15, the microchip 1500 may include a semiconductor circuit unit 1510 and a built-in memory 1520. In some example embodiments, the semiconductor circuit unit 1510 may include, but is not limited to, a system semiconductor circuit such as a central processing unit (CPU), a graphic processing unit (GPU), a micro controller unit (MCU), etc. The built-in memory 1520 may be used as a memory for storing data generated in the semiconductor circuit unit 1510. In some example embodiments, the built-in memory 1520 may include at least a nonvolatile vertical memory (NVM), and the NVM may include one of the first to fourth unit memory devices 100, 200, 300, and 400 illustrated in FIGS. 1, 3, 4, and 5, or one of the self-selecting memory devices 900, 1000, and 1200 illustrated in FIGS. 9, 10, and 12.

The semiconductor unit 1510 may communicate with the built-in memory 1520 to exchange information such as but not limited to data and/or instructions, communicated over a bus such as but not limited to a wireless and/or a wired bus. The information may be analog and/or digital without being limited thereto. The information may be sent and/or received in various manners, such as in a one-way, or two-way, or multiway (broadcast) manner; example embodiments are not limited thereto. The information may be sent serially and/or in parallel; example embodiments are not limited thereto.

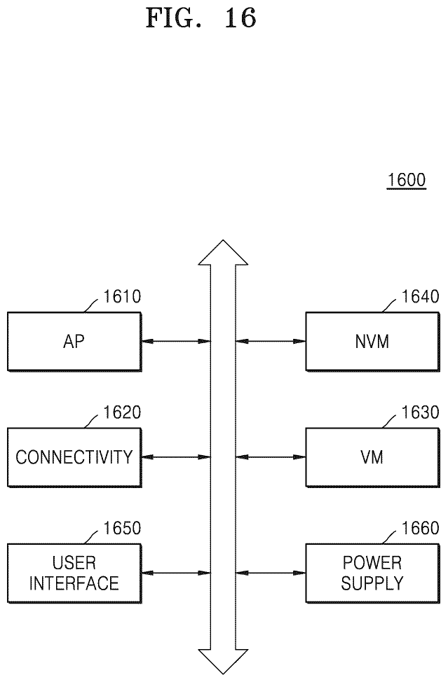

FIG. 16 is a block diagram showing an electronic system 1600 according to some example embodiments.

Referring to FIG. 16, the electronic system 1600 may include an application processor (AP) 1610, a connectivity unit 1620, a volatile memory device (VM) 1630, a nonvolatile memory device (NVM) 1640, a user interface 1650, and a power supply 1660. As an example, the electronic system 1600 may be a mobile system or may include a mobile system.

The AP 1610 may execute applications that provide an Internet browser, a game, a video, etc. The connectivity unit 1620 may perform wireless or wired communication with an external device.

The volatile memory device 1630 may store data processed by the AP 1610 or may function as a working memory. The nonvolatile memory device 1640 may store a boot image for booting the electronic system 1600. The user interface 1650 may include one or more input devices, such as a keypad, a touch screen, and/or one or more output devices, such as a speaker, a display device. The power supply 1660 may supply an operating voltage of the electronic system 1600. In addition, according to some example embodiments, the electronic system 1600 may further include a camera image processor CIS, and may further include a storage device, such as one or more of a memory card, a solid-state drive (SSD), a hard disk drive (HDD), a CD-ROM, etc.

In some example embodiments, the nonvolatile memory device 1640 may include one of the first to fourth unit memory devices 100, 200, 300, and 400 illustrated in FIGS. 1, 3, 4, and 5, or one of the self-selecting memory devices 900, 1000, and 1200 illustrated in FIGS. 9, 10, and 12.

The first to fourth unit memory devices 100, 200, 300, and 400 or the self-selecting memory devices 900, 1000, and 1200 according to the example embodiments described above may be used for data storage in various electronic apparatuses.

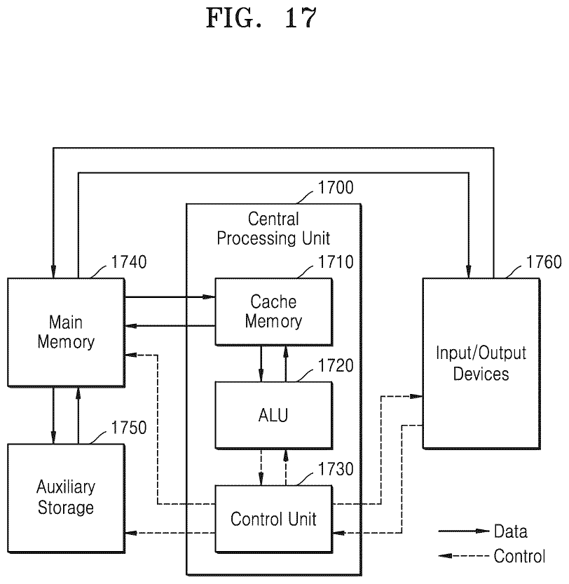

FIG. 17 is a conceptual diagram schematically showing a device architecture that may be applied to an electronic apparatus according to some example embodiments.

Referring to FIG. 17, a cache memory 1710, an arithmetic logic unit (ALU) 1720, and a control unit 1730 may constitute a CPU 1700, and the cache memory 1710 may include a static random-access memory (SRAM). Separately from the CPU 1700, a main memory 1740 and an auxiliary storage 1750 may be provided. The main memory 1740 may include a DRAM device, and the auxiliary storage 1750 may include the self-selecting memory devices 900, 1000, and 1200. In some cases, the device architecture may be implemented in a form in which computing unit devices and memory unit devices are adjacent to each other in one chip without distinction of sub-units.

The self-selecting memory devices 900, 1000, and 1200 according to the example embodiments described above may be implemented as memory blocks in the form of chips and may be used as a neuromorphic computing platform or may be used to configure a neural network.

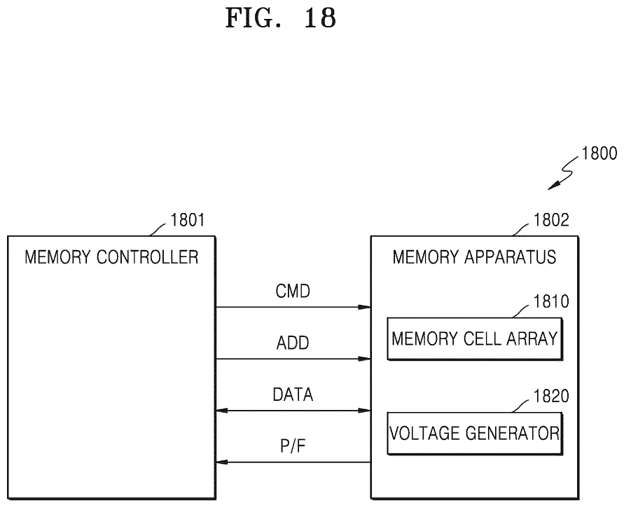

FIG. 18 is a block diagram of a memory system 1800 according to some example embodiments.

Referring to FIG. 18, the memory system 1800 may include a memory controller 1801 and a memory apparatus 1802. The memory controller 1801 may perform a control operation for the memory apparatus 1802. For example, the memory controller 1801 may provide an address ADD to the memory apparatus 1802 and a command CMD for performing a programming (or writing), reading, and/or erasing operation for the memory apparatus 1802. Additionally, data for programming operations and read data may be transmitted between the memory controller 1801 and the memory apparatus 1802.

The memory apparatus 1802 may include a memory cell array 1810 and a voltage generator 1820. The memory cell array 1810 may include a plurality of memory cells and may include the self-selecting memory devices 900, 1000, and 1200 according to the example embodiments described above.

The memory controller 1801 may include processing circuit such as hardware including logic circuit; hardware/software combinations such as processor execution software; or a combination thereof. For example, the processing circuit may be or may include, more specifically, one or more of a CPU, an ALU, a digital signal processor, a microcomputer, a field programmable gate array (FPGA), a system-on-chip (SoC), a programmable logic unit, a microprocessor, an application-specific integrated circuit (ASIC), etc., but is not limited thereto. The memory controller 1801 may operate in response to a request from a host (not shown). The memory controller 1801 may access the memory apparatus 1802 and control the control operations described above (e.g., write/read operations). Accordingly, the memory controller 1801 may also be configured to function as a special purpose controller. The memory controller 1801 may generate an address ADD and a command CMD to perform a programming writing/reading/erasing operation on the memory cell array 1810. In addition, in response to a command from the memory controller 1801, the voltage generator 1820 (e.g., a power circuit) may generate a voltage control signal to control a voltage level of a word line for data programming or data reading to the memory cell array 1810.

Alternatively or additionally, the memory controller 1801 may perform a decision operation on data read from the memory apparatus 1802. For example, the number of on-cells and/or the number of off-cells may be determined from data read from the memory cells. The memory apparatus 1802 may provide a pass/fail (P/F) signal to the memory controller 1801 based on the read result for the read data. The memory controller 1801 may control the write and read operations of the memory cell array 1810 by referring to the P/F signal.

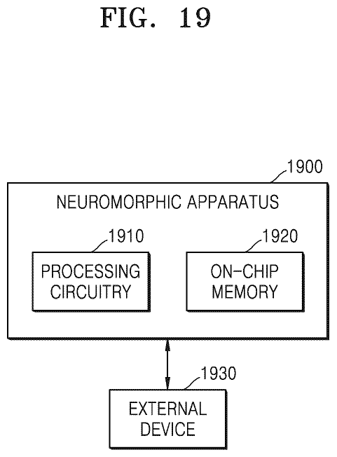

FIG. 19 is a block diagram showing a neuromorphic apparatus 1900 and an external device connected thereto according to some example embodiments.

Referring to FIG. 19, the neuromorphic apparatus 1900 may include a processing circuitry 1910 and/or an on-chip memory 1920. The neuromorphic apparatus 1900 may include one of the self-selecting memory devices 900, 1000, and 1200 according to the example embodiment described above.

In some example embodiments, the processing circuitry 1910 may be configured to control functions for driving the neuromorphic apparatus 1900. For example, the processing circuitry 1910 may be configured to control the neuromorphic apparatus 1900 by executing a program stored in the on-chip memory 1920. In some embodiments, the processing circuitry 1910 may include hardware such as a logic circuit, a hardware/software combination such as a processor executing software, or a combination thereof. In some example embodiments, the processor may include, but is not limited to, a CPU, a GPU, an AP included in the neuromorphic apparatus 1900, an ALU, a digital signal processor, a microcomputer, an FPGA, an SoC, a programmable logic unit, a microprocessor, an ASIC, and the like. In some example embodiments, the processing circuitry 1910 may be configured to read/write various data with respect to an external device 1930, and/or execute the neuromorphic apparatus 1900 using the read/written data. In some embodiments, the external device 1930 may include an external memory and/or a sensor array having an image sensor (e.g., a CMOS image sensor circuit).

In some example embodiments, the neuromorphic apparatus 1900 of FIG. 19 may be applied to a machine learning system. The machine learning systems may utilize various artificial neural network organization and processing models, such as convolutional neural networks (CNNs), deconvolutional neural networks, recurrent neural networks (RNNs) that optionally include long short-term memory (LSTM) units and/or gated recurrent units (GRUs), stacked neural networks (SNNs), state-space dynamic neural networks (SSDNNs), deep faith networks (DBNs), generative adversarial networks (GANs), and/or restricted Boltzmann machines (RBMs).

Alternatively or additionally, such machine learning systems may include combinations of other forms of machine learning models, such as linear and/or logistic regression, statistical clustering, Bayesian classification, decision trees, dimensionality reduction such as principal component analysis, expert systems, and/or ensembles such as random forests. Such machine learning models may be used to provide various services and/or applications, such as image classification services, user authentication services based on biometric information or biometric data, Advanced Driver Assistance System (ADAS) services, voice assistant services, automatic speech recognition (ASR) services, etc., which may be executed by electronic apparatuses.

The disclosed memory device is or includes a self-selecting memory. Therefore, the disclosed memory device may have a high integration density compared to a non-self-selecting memory and may be operated at high speed. Alternatively or additionally, the disclosed memory device includes GeAsTe as a memory material layer (memory layer), and the contents of Ge and Te are limited to a specific range. Accordingly, the set threshold voltage of the memory material layer of the disclosed memory device is less than 2 V, the reset threshold voltage is also less than 3 V, and a sufficient read window (memory window) may also be secured.

Therefore, the disclosed memory device may be used as a memory (e.g., embedded NVM) that requires low power, high-speed operation, and high integration. In addition, the disclosed memory device may have greater expandability because its low-power characteristics or memory characteristics do not change significantly even when its size is reduced.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While many matters have been described in detail in the above description, they should be construed as illustrative of some example embodiments rather than to limit the scope of the disclosure. Therefore, the scope of inventive concepts should not be defined by example embodiments described above, but should be determined by the technical spirit described in the claims.

It should be understood that example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory material comprising:
a composition represented by A(x)D(y)M(z),
wherein A includes germanium (Ge), D includes arsenic (As), and M includes tellurium (Te), and x satisfies 0<x<0.45, z satisfies 0.45<z<1, and y=1−(x+z).

2. The memory material of claim 1, further comprising:
a dopant.

3. The memory material of claim 2, wherein the dopant includes at least one of indium (In), selenium (Se), sulfur(S), antimony (Sb), nitrogen (N), and aluminum (Al).

4. A memory device comprising:
a plurality of memory cells,
wherein each memory cell includes a memory material layer between a first wiring and a second wiring at an intersection of the first wiring and the second wiring that intersect each other, each memory cell having a characteristic in which a threshold voltage shifts depending on an applied voltage,
wherein the memory material layer comprises a composition represented by A(x)D(y)M(z),
wherein A includes germanium (Ge), D includes arsenic (As), M includes tellurium (Te), and x satisfies 0<x<0.45, z satisfies 0.45<z<1, and y=1−(x+z).

5. The memory device of claim 4, wherein the first and second wirings and the memory material layer are in direct contact with each other.

6. The memory device of claim 4, further comprising:
a first electrode layer between a first side of the memory material layer and the first wiring; and
a second electrode layer between a second side of the memory material layer and the second wiring, the second side being different from the first side.

7. The memory device of claim 6, further comprising:
a first dielectric layer between the first side of the memory material layer and the first electrode layer.

8. The memory device of claim 7, further comprising:
a second dielectric layer between the second side of the memory material layer and the second electrode layer.

9. The memory device of claim 4, further comprising:
a first dielectric layer between the memory material layer and the first wiring.

10. The memory device of claim 9, further comprising:
a second dielectric layer between the memory material layer and the second wiring.

11. The memory device of claim 4, wherein the memory material layer further includes a dopant.

12. The memory device of claim 11, wherein the dopant includes at least one of In, Se, S, Sb, N, and Al.

13. The memory device of claim 4, wherein the memory device has a three-dimensional cross point structure.

14. The memory device of claim 4, wherein the memory device includes a vertical NAND (VNAND) structure.

15. The memory device of claim 14, wherein the plurality of memory cells are arranged in a third direction perpendicular to a plane defined by first and second directions.

16. The memory device of claim 15, further comprising:
a plurality of word planes extending along a plane defined by the first and second directions and spaced apart in the third direction;
a vertical bit line extending in the third direction through the plurality of word planes; and
a memory cell string surrounding the vertical bit line and extending in the third direction,
wherein the memory cell string and the vertical bit line that are surrounded by each word plane and each word plane constitute one memory cell.

17. The memory device of claim 4, wherein the memory material layer is configured to be in one of a first state having a first threshold voltage or a second state having a second threshold voltage greater than the first threshold voltage.

18. The memory device of claim 17, wherein
the first threshold voltage is a set threshold voltage,
the second threshold voltage is a reset threshold voltage, and
the reset threshold voltage is lower than 3V.

19. An electronic apparatus comprising the memory device of claim 4.

20. The electronic apparatus of claim 19, further comprising:
a semiconductor circuit unit,
wherein the memory device is a built-in memory for the semiconductor circuit unit and is included in one chip with the semiconductor circuit unit.
